(19) United States
(12) Patent Application Publication
(10) Pub. No.: US 2020/0209744 A1
(43) Pub. Date: Jul. 2, 2020

(54) Photosensitive dry film sheets

(71) Applicants: Donald W Johnson, Wayland, MA (US); Malkaye Kpante, Lowell, MA (US)

(72) Inventors: Donald W Johnson, Wayland, MA (US); Malkaye Kpante, Lowell, MA (US)

(21) Appl. No.: 16/731,373

(22) Filed: Dec. 31, 2019

Related U.S. Application Data
(60) Provisional application No. 62/786,956, filed on Dec. 31, 2018.

(51) Int. Cl. G03F 7/038; G03F 7/004; G03F 7/039

(52) U.S. Cl. CPC G03F 7/0385; G03F 7/0392; G03F 7/0045

(57) ABSTRACT

Methods and systems for creating photosensitive dry film sheets are disclosed. The systems and methods described herein may include exposing a resin comprising a photoacid generator to at least one of 325-425 nm ultraviolet radiation and X-ray radiation, generating, with the photoacid generator, an acid upon exposure to the at least one of the X-ray radiation and the 325-425 nm ultraviolet radiation. The systems and methods described herein may then include heating the exposed resin and cross-linking the exposed resin with the acid.

### CROSS-REFERENCE TO RELATED APPLICATIONS

The present application claims the benefit of and priority to U.S. provisional application No. 62/786,956, filed on Dec. 31, 2018, the entire disclosure of which is hereby incorporated by reference as if set forth in its entirety herein.

### TECHNICAL FIELD

Embodiments described herein generally relate to methods and systems for creating photosensitive dry film sheets and, more particularly but not exclusively, to methods and systems for creating photosensitive dry film sheets that generate acid upon exposure to radiation.

### BACKGROUND

Liquid photoresist materials, including light-sensitive organic resin solutions, have been used in photolithography and photoengraving processes to form a patterned coating on substrates, such as silicon, glass, copper, gold, and polymer film. This process has been used for manufacturing semiconductors, microelectromechanical systems (MEMS), microsensors for electronic devices and printed circuit boards.

After coating a substrate with a photosensitive film, a patterned photomask is then applied to the surface to selectively block light, so that only unmasked regions of the material will be exposed to light. The photosensitive material is then either cross-linked, polymerized or rendered soluble by light often followed by heating. A solvent or aqueous solution, called a developer, is then applied to the surface dissolving away either the exposed or unexposed regions, depending on whether the resist is positive acting or negative acting, and leaving behind a coating over the undissolved areas of the surface which are then subjected to further processing. These processes frequently have long drying times and can leave residue on the film. Solid resin products may contain difficult to remove solvents, adsorbed water, or solid contaminates and may create surface craters, bubbles, voids, and microparticulates

Some resin formulations can be used to manufacture dry film sheets through lamination. However, the current manufacturing processes can result in inconsistent covering of film sheets, particularly as the thickness of the sheet increases. A need exists, therefore, for systems and methods for overcoming the disadvantages of existing techniques.

### SUMMARY

This summary is provided to introduce a selection of concepts in a simplified form that are further described below in the Detailed Description section. This summary is not intended to identify or exclude key features or essential features of the claimed subject matter, nor is it intended to be used as an aid in determining the scope of the claimed subject matter.

In one aspect, embodiments relate to a photosensitive dry film sheet. The photosensitive dry film sheet includes a resin, the resin comprising a photoacid generator, wherein the photoacid generator is configured to generate an acid upon exposure to at least one of 325-425 nm ultraviolet radiation and X-ray radiation, and the generated acid, upon exposure to heat having a temperature above 30° C., is configured to react with the resin to cross-link the resin.

In some embodiments, the photoacid generator is at least one of a diaryliodonium fluoroalkyl polyfluorophosphate salt and a triarylsulfonyl-fluoroalkyl polyfluorophosphate salt.

In some embodiments, the resin includes at least one of a SU-8 epoxy resin, a bisphenol-A epichlorohydrin epoxy resin, a glycidyloxypropyltrimethoxysilane silicone fluid, a dimethylsiloxane silicone fluid, and a resin modifier. In some embodiments, the resin modifier has a viscosity between 1,000 and 10,000 cP at 25° C. In some embodiments, the resin modifier has a hydroxyl number between 100 and 400.

In some embodiments, the photosensitive dry film sheet of claim 1 further includes a surface wetting agent. In some embodiments, the surface wetting agent includes at least one of glycidyloxypropyltrimethoxysilane and dimethylsiloxane silicone fluid.

In some embodiments, the photoacid generator includes at least one of:

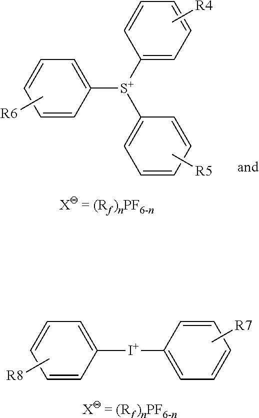

wherein: R4, R5, R6, R7, and R8 are independently selected from H, alkyl, aryl, ester, amide, amine, nitrile, ether, and alcohol, R_{f} is an alkyl fluoride, X⁻ is a counterion, and n is an integer from 0 to 5.

In another aspect, embodiments relate to a method for creating a photosensitive dry film sheet. The method includes exposing a resin comprising a photoacid generator to at least one of 325-425 nm ultraviolet radiation and X-ray radiation, generating, with the photoacid generator, an acid upon exposure to the at least one of the X-ray radiation and the 325-425 nm ultraviolet radiation, heating the exposed resin to a temperature above 30° C., and cross-linking the exposed resin with the acid.

In some embodiments, exposure to the at least one of the X-ray radiation and the 325-425 nm ultraviolet radiation includes exposure through a patterned photomask.

In some embodiments, the exposed resin is cross-linked with the acid in a pre-defined imaged area. In some embodiments, the resin has a melt viscosity below 5000 centistokes at 120° C.

In some embodiments, the method further includes mixing the resin and the photoacid generator at a temperature between 120° C. and 150° C. and filtering the mixture through a microfiber filter.

In some embodiments, the method includes degassing the mixture.

In some embodiments, the photoacid generator includes at least one of:

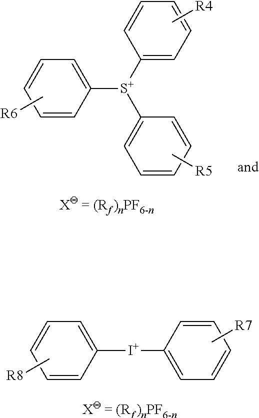

wherein: R4, R5, R6, R7, and R8 are independently selected from H, alkyl, aryl, ester, amide, amine, nitrile, ether, and alcohol, R_{f} is an alkyl fluoride, X⁻ is a counterion, and n is an integer from 0 to 5.

In some embodiments, the method further includes mixing the resin with a surface wetting agent. In some embodiments, the resin includes at least one of a SU-8 epoxy resin, a bisphenol-A epichlorohydrin epoxy resin, a glycidyloxypropyltrimethoxysilane silicone fluid, a dimethylsiloxane silicone fluid, and a resin modifier.

In some embodiments, the resin modifier has a viscosity between 1,000 and 10,000 cP at 25° C. In some embodiments, the resin modifier has a hydroxyl number between 100 and 400.

In some embodiments, the dry film sheet is ultraviolet radiation sensitive and the photoacid generator is a triarylsulfonyl-fluoroalkyl polyfluorophosphate salt.

### BRIEF DESCRIPTION OF DRAWINGS

Non-limiting and non-exhaustive embodiments of this disclosure are described with reference to the following figures, wherein like reference numerals refer to like parts throughout the various views unless otherwise specified.

FIG. 1 illustrates a method for creating and activating a photosensitive dry film sheet in accordance with one embodiment; and

FIG. 2 illustrates a method for creating a resin in accordance with one embodiment.

### DETAILED DESCRIPTION

Various embodiments are described more fully below with reference to the accompanying drawings, which form a part hereof, and which show specific exemplary embodiments. However, the concepts of the present disclosure may be implemented in many different forms and should not be construed as limited to the embodiments set forth herein; rather, these embodiments are provided as part of a thorough and complete disclosure, to fully convey the scope of the concepts, techniques and implementations of the present disclosure to those skilled in the art. Embodiments may be practiced as methods, systems or devices. Accordingly, embodiments may take the form of a hardware implementation, an entirely software implementation or an implementation combining software and hardware aspects. The following detailed description is, therefore, not to be taken in a limiting sense.

Reference in the specification to “one embodiment” or to “an embodiment” means that a particular feature, structure, or characteristic described in connection with the embodiments is included in at least one example implementation or technique in accordance with the present disclosure. The appearances of the phrase “in one embodiment” in various places in the specification are not necessarily all referring to the same embodiment. The appearances of the phrase “in some embodiments” in various places in the specification are not necessarily all referring to the same embodiments.

In addition, the language used in the specification has been principally selected for readability and instructional purposes and may not have been selected to delineate or circumscribe the disclosed subject matter. Accordingly, the present disclosure is intended to be illustrative, and not limiting, of the scope of the concepts discussed herein.

In accordance with the embodiments described herein, a photosensitive dry film resist sheet may include a resin having a photoacid generator. In some embodiments, the photoacid generator is configured to generate an acid when exposed to radiation. The acid generated during the exposure may be configured to react with the resin to cross-link the resin in some embodiments.

In some embodiments, the methods described herein produce dry films from 5 μm to over 500 μm thick that can be laminated to a wide variety of substrates. In some embodiments, the films are solid at room temperature, contain less than 2% residual solvent, tacky at temperatures above room temperature, and are coated at better than 5% uniformity. In some embodiments, the methods described herein produce dry films that are cross linkable after exposure to ultraviolet radiation, excimer laser or x-ray radiation. In some embodiments, the methods described herein produce dry films that will not crosslink at elevated temperatures up to 150° C. without radiation exposure. In some embodiments, dry films do not contain contaminants larger than 1 μm in diameter.

In some embodiments, various curable resins, frequently epoxy resins, resin modifiers and other additives that are stable to the elevated temperatures of the blending and coating processes may be mixed with one or more photoacid generators (PAGs). Some embodiments may use photoacid generators such as the toxic triaryl sulfonium hexafluoroantimonate salt, CPI-101A, tris((trifluoromethyl)sulfonyl)methide salts (such as Irgacure GSID-26-1, BASF), triaryl sulfonium tetrakis[pentafluorophenyl]borate salts (such as Irgacure 290, BASF and CPI-310B, San Apro), thiophenylphenyl-diarylsulfonium polyfluoroalkyl-fluorophosphate salts, CPI200S and CPI210S, triarylsulfonyl-polyfluoroalkyl-fluorophosphate salts such as CPI410S, and diaryl iodonium polyfluoroalkyl-fluorophosphate salts. These identification numbers and their corresponding structures can be found in High Lights! Radiation curing with resins and photoinitiators for industrial coatings and graphic arts: Photoinitiator selection guide, BASF: The Chemical Company, the entire disclosure of which is hereby incorporated by reference as if set forth in its entirety wherein.

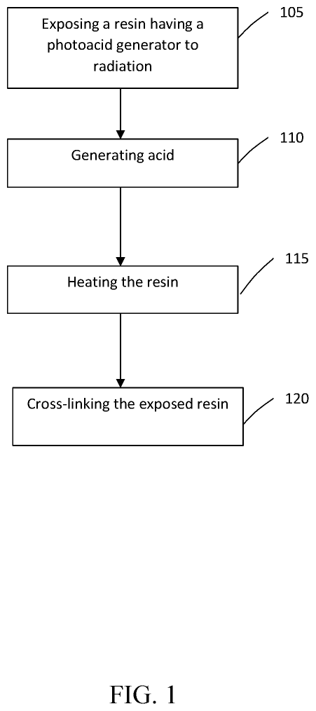

For example, FIG. 1 illustrates a method for creating and activating a photosensitive dry film sheet in accordance with one embodiment. In some embodiments, a dry film sheet may have a resin and a photoacid generator in the resin. The resin may be exposed to radiation 105 to activate the photoacid generator. In some embodiments the photoacid generator may be exposed to ultraviolet radiation. In some embodiments, the ultraviolet radiation may include wavelengths between 325 nm and 425 nm. In some embodiments, the ultraviolet radiation may include wavelengths between 350 nm and 400 nm. In some embodiments, the photoacid generator may be exposed to X-ray radiation. In some embodiments, only one photoacid generator may be included in a resin. In some embodiments, a plurality of photoacid generators may be included in a resin. In some embodiments, the single photoacid generator may be sensitive only to one of X-ray or ultraviolet radiation. In some embodiments, the single photoacid generator may be sensitive both X-ray and ultraviolet radiation. In some embodiments, the mixture of photoacid generators may be sensitive only to one of X-ray or ultraviolet radiation. In some embodiments, the mixture of photoacid generators may be sensitive to both X-ray and ultraviolet radiation.

In some embodiments, the photoacid generator is at least one of a diaryliodonium fluoroalkyl polyfluorophosphate salt and a triarylsulfonyl-fluoroalkyl polyfluorophosphate salt. In some embodiments, a triarylsulfonyl-fluoroalkyl polyfluorophosphate salt may generate acid when exposed to ultraviolet radiation. In some embodiments, a diaryliodonium fluoroalkyl polyfluorophosphate salt may generate acid when exposed to X-ray radiation. The photoacid generator, in some embodiments, may include

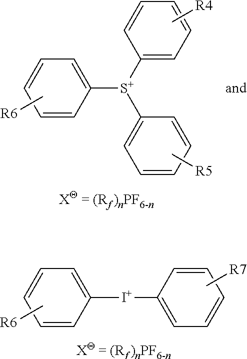

wherein: R4, R5, R6, R7, and R8 are independently selected from H, alkyl, aryl, ester, amide, amine, nitrile, ether, and alcohol, R_{f} is an alkyl fluoride, X⁻ is a counterion, and n is an integer from 0 to 5.

Some embodiments may use other thermally stable trifluoromethyl)sulfonyl methanide or pentafluorophenylborate salts,

In some embodiments, after the resin is exposed to radiation 105, the photoacid generator in the acid may generate an acid 110. In some embodiments, after the acid is generated 110, the resin may be heated 115. In some embodiments, the resin may be heated 115 to a temperature above 30° C. In some embodiments, the resin may be heated 115 to a temperature above 35° C. In some embodiments, the resin may be heated 115 to a temperature above 40° C. In some embodiments, the resin may be heated 115 to a temperature above 60° C. In some embodiments, the resin may be heated 115 to a temperature above 80° C. In some embodiments, the resin may be heated 115 to a temperature above 100° C. In some embodiments, the resin may be heated 115 to a temperature above 120° C. In some embodiments, the resin may be heated 115 to a temperature above 140° C.

In some embodiments, after heating the resin 115, the acid may react with the resin to cross-link the resin 120. In some embodiments, crosslinking may include any polymerization of the film.

In some embodiments, only the resin exposed to the radiation will generate the acid 110 and only the exposed resin will cross-link 120 when the resin is heated 115. For example, in some embodiments, the resin may be exposed to radiation 105 through a patterned photomask. In some embodiments, the patterned photomask may be a pre-defined image area. In some embodiments, only resin exposed through the patterned photomask generates acid 110 identical to the shape of the patterned photomask. Resin blocked from radiation exposure by the patterned photomask does not generate acid in some embodiments. In some embodiments, when the resin on the sheet is heated 115, the patterned acid cross-links the exposed resin 120 in areas where the resin was exposed to radiation 105 and does not cross-link the resin that was blocked from radiation exposure.

In some embodiments, a direct write excimer laser beam or other tool may be used to define a patterned image area.

In some embodiments, commercial hot melt coating equipment may be used to coat the dry film.

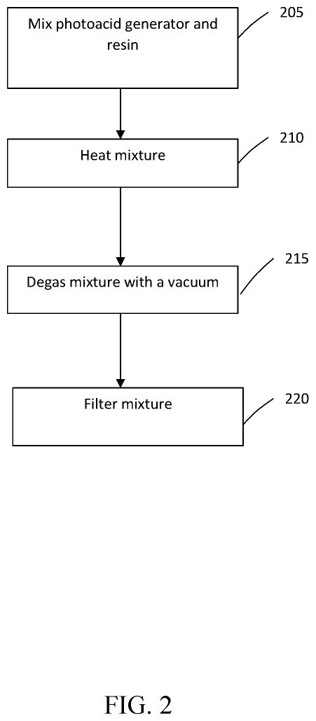

FIG. 2 illustrates a method for creating a resin used in the photosensitive dry film resist sheets in accordance with one embodiment. In some embodiments, a resin and a photoacid generator are mixed together 205. In some embodiments, the resin may be at least one of a SU-8 epoxy resin, a bisphenol-A epichlorohydrin epoxy resin, a glycidyloxypropyltrimethoxysilane silicone fluid, a dimethylsiloxane silicone fluid, and a resin modifier. In some embodiments, a resin may refer to a composite resin, resin blend, or mixture of resin, resin modifiers, and photoacid generators. In some embodiments, the resin modifier of a resin has a viscosity between 1,000 and 10,000 cP at 25° C. In some embodiments, the resin modifier has a hydroxyl number between 100 and 400.

In some embodiments, the vessel containing the mixture of resins, resin modifiers, and photoacid generators may be heated 210. In some embodiments, the photoacid generator may be heated and then mixed with a resin. In some embodiments, the mixture of the photoacid generators, resins, and resin modifiers may not be heated above 130° C. In some embodiments, a mixture of the photoacid generators, resins, and resin modifiers may be heated to a temperature between 120° C. and 150° C.

In some embodiments, after heating the mixture 210, the mixture may be degassed with a vacuum 215. In some embodiments, the mixture may be heated to 120° C. before degassing 215. In some embodiments, the mixture may be heated to 150° C. before degassing 215. In some embodiments, the vacuum may be used to degas the mixture to 100-150 torr. In some embodiments, the mixture may be heated to 120-150° C. for 12-24 hours. In some embodiments, the mixture may not be degassed In some embodiments, the vacuum may be applied slowly to avoid excess foaming.

In some embodiments, the degassed mixture may be filtered 220. In some embodiments, the mixture may be filtered with a 100 μm stainless steel filter. In some embodiments, the mixture may be filtered with a microfiber filter. In some embodiments, the filter may be made of glass or stainless steel. In some embodiments, the mixture may be filtered with sub-micron fibers of smaller than 1 μm. In some embodiments, the mixture may be filtered with sub-micron fibers of 0.5 μm. In some embodiments, the filter may be stable at temperatures of more than 100° C. or more than 120° C.

In some embodiments, the mixture may be applied to a film.

In some embodiments, the photosensitive dry film sheet of claim 1 further includes a surface wetting agent. In some embodiments, the surface wetting agent includes at least one of glycidyloxypropyltrimethoxysilane and dimethylsiloxane silicone fluid.

In some embodiments, the resin may have a melt viscosity below 5000 centistokes at 120° C.

Examples of preparing the resin are further described below.

Ex. 1: A resin formulation may be made from 500 gm of SU-8 epoxy resin, 475 gm of a low MW bisphenol-A epichlorohydrin epoxy resin, 20 gm of glycidyloxypropyltrimethoxysilane, and 5 gm of a polyfluorophosphate photoacid generator. The above ingredients are combined in an appropriate size metal or glass container and heating in an oven at 120-150° C. until melted. The mixture is then periodically stirred until a homogeneous mixture is formed. The mixture is then filtered through a <5 μm microfiber filter, degassed and allowed to solidify.

Ex. 2: A resin formulation may be made from 465 gm of SU-8 epoxy resin, 460 gm of a low MW bisphenol-A epichlorohydrin epoxy resin, 70 gm of a 9500 cps/250 OH # resin modifier and 4 gm of a polyfluorophosphate photoacid generator. The above ingredients are combined in an appropriate size metal or glass container and heating in an oven at 120-150° C. until melted. The mixture is then periodically stirred until a homogeneous mixture is formed. The mixture is then filtered through a <5 μm microfiber filter, degassed and allowed to solidify.

Ex. 3: A resin formulation may be made from 450 gm of SU-8 epoxy resin, 465 gm of a low MW bisphenol-A epichlorohydrin epoxy resin, 70 gm of a 9500 cps/250 OH # resin modifier, 20 gm of dimethylsiloxane silicone fluid, and 4 gm of a diaryl iodonium polyfluoroalkyl-fluorophosphate salt. The above ingredients are combined in an appropriate size metal or glass container and heating in an oven at 120-150° C. until melted. The mixture is then periodically stirred until a homogeneous mixture is formed. The mixture is then filtered through a <5 μm microfiber filter, degassed and allowed to solidify.

Ex. 4: A resin formulation may be made from 450 gm of SU-8 epoxy resin, 455 gm of a low MW bisphenol-A epichlorohydrin epoxy resin, 70 gm of a 11000 cps/100 OH # resin modifier, 20 gm of glycidyloxypropyltrimethoxysilane, and 4 gm of a polyfluorophosphate photoacid generator. The above ingredients are combined in an appropriate size metal or glass container and heating in an oven at 120-150° C. until melted. The mixture is then periodically stirred until a homogeneous mixture is formed. The mixture is then filtered through a <5 μm microfiber filter, degassed and allowed to solidify.

Ex. 5: A resin formulation may be made from 435 gm of SU-8 epoxy resin, 555 gm of a low MW bisphenol-A epichlorohydrin epoxy resin, 50 gm of a 9500 cps/250 OH # resin modifier, 20 gm of glycidyloxypropyltrimethoxysilane and 4 gm of a polyfluorophosphate photoacid generator. The above ingredients are combined in an appropriate size metal or glass container and heating in an oven at 120-150° C. until melted. The mixture is then periodically stirred until a homogeneous mixture is formed. The mixture is then filtered through a <5 μm microfiber filter, degassed and allowed to solidify.

Ex. 6: A resin formulation may be made from 420 gm of SU-8 epoxy resin, 440 gm of a low MW bisphenol-A epichlorohydrin epoxy resin, 60 gm of a 7000 cps/350 OH # resin modifier, 20 gm of dimethylsiloxane silicone fluid, and 7 gm of a diaryl iodonium polyfluoroalkyl-fluorophosphate salt. The above ingredients are combined in an appropriate size metal or glass container and heating in an oven at 120-150° C. until melted. The mixture is then periodically stirred until a homogeneous mixture is formed. The mixture is then filtered through a <5 μm microfiber filter, degassed and allowed to solidify.

Ex. 7: A resin formulation may be made from 420 gm of SU-8 epoxy resin, 420 gm of a low MW bisphenol-A epichlorohydrin epoxy resin, 70 gm of a 4500 cps/150 OH # resin modifier, 20 gm of glycidyloxypropyltrimethoxysilane and 8 gm of a polyfluorophosphate photoacid generator. The above ingredients are combined in an appropriate size metal or glass container and heating in an oven at 120-150° C. until melted. The mixture is then periodically stirred until a homogeneous mixture is formed. The mixture is then filtered through a <5 μm microfiber filter, degassed and allowed to solidify.

Ex. 8: A resin formulation may be made from 420 gm of SU-8 epoxy resin, 400 gm of a low MW bisphenol-A epichlorohydrin epoxy resin, 80 gm of a 1500 cps/250 OH # resin modifier, 20 gm of glycidyloxypropyltrimethoxysilane and 8 gm of a polyfluorophosphate photoacid generator. The above ingredients are combined in an appropriate size metal or glass container and heating in an oven at 120-150° C. until melted. The mixture is then periodically stirred until a homogeneous mixture is formed. The mixture is then filtered through a <5 μm microfiber filter, degassed and allowed to solidify.

In some embodiments, the resin formulation maybe made from 40-50% SU-8 Epoxy resin; 40-50% BPA-ECH resin, 6-8% resin modifier, 1-3% silane, and 0-2% TASFA PFP, wherein all percentages are weight percentages. In some embodiments, the resin formulation maybe made from 44.6% SU-8 Epoxy resin; 46% BPA-ECH resin, 7% resin modifier, 2% silane, and 0.4% TASFA PFP, wherein all percentages are weight percentages.

In some embodiments, the resin formulation maybe made from 40-50% SU-8 Epoxy resin; 40-50% BPA-ECH resin, 6-8% resin modifier, 1-3% silane, and 0-2% DAISFA PFP, wherein all percentages are weight percentages. In some embodiments, the resin formulation maybe made from 44.6% SU-8 Epoxy resin; 46% BPA-ECH resin, 7% resin modifier, 2% silane, and 0.4% DAISFA PFP, wherein all percentages are weight percentages.

In some embodiments, the resin formulation maybe made from 40-50% SU-8 Epoxy resin; 40-50% BPA-ECH resin, 6-8% resin modifier, 1-3% silane, and 0-2% Irgacure 290, wherein all percentages are weight percentages. In some embodiments, the resin formulation maybe made from 45% SU-8 Epoxy resin; 45.6% BPA-ECH resin, 7% resin modifier, 2% silane, and 0.4% Irgacure 290, wherein all percentages are weight percentages.

In some embodiments, the resin formulation maybe made from 40-50% SU-8 Epoxy resin; 40-50% BPA-ECH resin, 5-8% resin modifier, 1-3% silane, and 0-10% TASFA PFP, wherein all percentages are weight percentages. In some embodiments, the resin formulation maybe made from 43.6% SU-8 Epoxy resin; 45.4% BPA-ECH resin, 7% resin modifier, 2% silane, and 4% TASFA PFP, wherein all percentages are weight percentages. In some embodiments, the resin formulation maybe made from 43% SU-8 Epoxy resin; 45% BPA-ECH resin, 6% resin modifier, 2% silane, and 4% TASFA PFP, wherein all percentages are weight percentages. In some embodiments, the resin formulation maybe made from 42% SU-8 Epoxy resin; 44% BPA-ECH resin, 7% resin modifier, 2% silane, and 5% TASFA PFP, wherein all percentages are weight percentages. In some embodiments, the resin formulation maybe made from 42% SU-8 Epoxy resin; 42% BPA-ECH resin, 8% resin modifier, 2% silane, and 6% TASFA PFP, wherein all percentages are weight percentages.

In some embodiments, the resin formulation maybe made from 40-50% SU-8 Epoxy resin; 40-50% Epoxynovolak, 4-8% resin modifier, 1-3% silane, and 0-5% TASFA PFP, wherein all percentages are weight percentages. In some embodiments, the resin formulation maybe made from 44.5% SU-8 Epoxy resin; 44.5% Epoxynovolak, 5% resin modifier, 2% silane, and 4% TASFA PFP, wherein all percentages are weight percentages

In some embodiments, a resin modifier may be added to the resin blend. In some embodiments, the resin modifier may have a viscosity number of 9500 and a hydroxyl number of 250. In some embodiments, the resin modifier may have a viscosity number of 11000 and a hydroxyl number of 100. In some embodiments, the resin modifier may have a viscosity number of 7000 and a hydroxyl number of 350. In some embodiments, the resin modifier may have a viscosity number of 4500 and a hydroxyl number of 150. In some embodiments, the resin modifier may have a viscosity number of 1500 and a hydroxyl number of 250.

Various embodiments are described with reference to the accompanying drawings, which form a part hereof, and which show specific exemplary embodiments. However, the concepts of the present disclosure may be implemented in many different forms and should not be construed as limited to the embodiments described herein; rather, these embodiments are provided as part of a thorough and complete disclosure, to fully convey the scope of the concepts, techniques and implementations of the present disclosure to those skilled in the art. Embodiments may be practiced as methods, systems or devices. Accordingly, embodiments may take the form of a hardware implementation, an entirely software implementation or an implementation combining software and hardware aspects. The previous detailed description is, therefore, not to be taken in a limiting sense.

Reference in the specification to “one embodiment” or to “an embodiment” means that a particular feature, structure, or characteristic described in connection with the embodiments is included in at least one example implementation or technique in accordance with the previous disclosure. The appearances of the phrase “in one embodiment” in various places in the specification are not necessarily all referring to the same embodiment. The appearances of the phrase “in some embodiments” in various places in the specification are not necessarily all referring to the same embodiments.

Some portions of the preceding description are presented in terms of symbolic representations of operations on non-transient signals stored within a computer memory. These descriptions and representations are used by those skilled in the data processing arts to most effectively convey the substance of their work to others skilled in the art. Such operations typically require physical manipulations of physical quantities. Usually, though not necessarily, these quantities take the form of electrical, magnetic or optical signals capable of being stored, transferred, combined, compared and otherwise manipulated. It is convenient at times, principally for reasons of common usage, to refer to these signals as bits, values, elements, symbols, characters, terms, numbers, or the like. Furthermore, it is also convenient at times, to refer to certain arrangements of steps requiring physical manipulations of physical quantities as modules or code devices, without loss of generality.

However, all of these and similar terms are to be associated with the appropriate physical quantities and are merely convenient labels applied to these quantities. Unless specifically stated otherwise as apparent from the previous discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system memories or registers or other such information storage, transmission or display devices. Portions of the present disclosure include processes and instructions that may be embodied in software, firmware or hardware, and when embodied in software, may be downloaded to reside on and be operated from different platforms used by a variety of operating systems.

The present disclosure also relates to an apparatus for performing the operations herein. This apparatus may be specially constructed for the required purposes, or it may comprise a general-purpose computer selectively activated or reconfigured by a computer program stored in the computer. Such a computer program may be stored in a computer readable storage medium, such as, but is not limited to, any type of disk including floppy disks, optical disks, CD-ROMs, magnetic-optical disks, read-only memories (ROMs), random access memories (RAMs), EPROMs, EEPROMs, magnetic or optical cards, application specific integrated circuits (ASICs), or any type of media suitable for storing electronic instructions, and each may be coupled to a computer system bus. Furthermore, the computers referred to in the specification may include a single processor or may be architectures employing multiple processor designs for increased computing capability.

The processes and displays presented herein are not inherently related to any particular computer or other apparatus. Various general-purpose systems may also be used with programs in accordance with the teachings herein, or it may prove convenient to construct more specialized apparatus to perform one or more method steps. The structure for a variety of these systems is discussed in the preceding description. In addition, any particular programming language that is sufficient for achieving the techniques and implementations of the present disclosure may be used. A variety of programming languages may be used to implement the present disclosure as discussed herein.

In addition, the language used in the specification has been principally selected for readability and instructional purposes and may not have been selected to delineate or circumscribe the disclosed subject matter. Accordingly, the present disclosure is intended to be illustrative, and not limiting, of the scope of the concepts discussed herein.

The methods, systems, and devices discussed above are examples. Various configurations may omit, substitute, or add various procedures or components as appropriate. For instance, in alternative configurations, the methods may be performed in an order different from that described, and that various steps may be added, omitted, or combined. Also, features described with respect to certain configurations may be combined in various other configurations. Different aspects and elements of the configurations may be combined in a similar manner. Also, technology evolves and, thus, many of the elements are examples and do not limit the scope of the disclosure or claims.

Embodiments of the present disclosure, for example, are described above with reference to block diagrams and/or operational illustrations of methods, systems, and computer program products according to embodiments of the present disclosure. The functions/acts noted in the blocks may occur out of the order as shown in any flowchart. For example, two blocks shown in succession may in fact be executed substantially concurrent or the blocks may sometimes be executed in the reverse order, depending upon the functionality/acts involved. Additionally, or alternatively, not all of the blocks shown in any flowchart need to be performed and/or executed. For example, if a given flowchart has five blocks containing functions/acts, it may be the case that only three of the five blocks are performed and/or executed. In this example, any of the three of the five blocks may be performed and/or executed.

A statement that a value exceeds (or is more than) a first threshold value is equivalent to a statement that the value meets or exceeds a second threshold value that is slightly greater than the first threshold value, e.g., the second threshold value being one value higher than the first threshold value in the resolution of a relevant system. A statement that a value is less than (or is within) a first threshold value is equivalent to a statement that the value is less than or equal to a second threshold value that is slightly lower than the first threshold value, e.g., the second threshold value being one value lower than the first threshold value in the resolution of the relevant system.

Specific details are given in the description to provide a thorough understanding of example configurations (including implementations). However, configurations may be practiced without these specific details. For example, well-known circuits, processes, algorithms, structures, and techniques have been shown without unnecessary detail in order to avoid obscuring the configurations. This description provides example configurations only, and does not limit the scope, applicability, or configurations of the claims. Rather, the preceding description of the configurations will provide those skilled in the art with an enabling description for implementing described techniques. Various changes may be made in the function and arrangement of elements without departing from the spirit or scope of the disclosure.

Having described several example configurations, various modifications, alternative constructions, and equivalents may be used without departing from the spirit of the disclosure. For example, the above elements may be components of a larger system, wherein other rules may take precedence over or otherwise modify the application of various implementations or techniques of the present disclosure. Also, a number of steps may be undertaken before, during, or after the above elements are considered.

Having been provided with the description and illustration of the present application, one skilled in the art may envision variations, modifications, and alternate embodiments falling within the general inventive concept discussed in this application that do not depart from the scope of the following claims.

What is claimed is:

1. A photosensitive dry film sheet comprising:
a resin, the resin comprising a photoacid generator; wherein:
the photoacid generator is configured to generate an acid upon exposure to at least one of 325-425 nm ultraviolet radiation and X-ray radiation; and
the generated acid, upon exposure to heat having a temperature above 30° C., is configured to react with the resin to cross-link the resin.

2. The photosensitive dry film sheet of claim 1, wherein the photoacid generator is at least one of a diaryliodonium fluoroalkyl polyfluorophosphate salt and a triarylsulfonyl-fluoroalkyl polyfluorophosphate salt.

3. The photosensitive dry film sheet of claim 1, wherein the resin comprises at least one of a SU-8 epoxy resin, a bisphenol-A epichlorohydrin epoxy resin, a glycidyloxypropyltrimethoxysilane silicone fluid, a dimethylsiloxane silicone fluid, and a resin modifier.

4. The photosensitive dry film sheet of claim 3, wherein the resin modifier has a viscosity between 1,000 and 10,000 cP at 25° C.

5. The photosensitive dry film sheet of claim 3, wherein the resin modifier has a hydroxyl number between 100 and 400.

6. The photosensitive dry film sheet of claim 1, further comprising a surface wetting agent.

7. The photosensitive dry film sheet of claim 6, wherein the surface wetting agent comprises at least one of glycidyloxypropyltrimethoxysilane and dimethylsiloxane silicone fluid.

8. The photosensitive dry film sheet of claim 1, wherein the photoacid generator comprises at least one of: 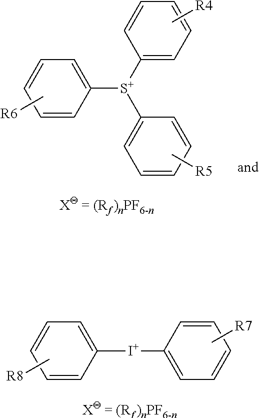
wherein:
R4, R5, R6, R7, and R8 are independently selected from H, alkyl, aryl, ester, amide, amine, nitrile, ether, and alcohol;
R_{f} is an alkyl fluoride;
X− is a counterion; and
n is an integer from 0 to 5.

9. A method for creating a photosensitive dry film sheet, the method comprising:
exposing a resin comprising a photoacid generator to at least one of 325-425 nm ultraviolet radiation and X-ray radiation;
generating, with the photoacid generator, an acid upon exposure to the at least one of the X-ray radiation and the 325-425 nm ultraviolet radiation;
heating the exposed resin to a temperature above 30° C.; and
cross-linking the exposed resin with the acid.

10. The method of claim 9 wherein exposure to the at least one of the X-ray radiation and the 325-425 nm ultraviolet radiation comprises exposure through a patterned photomask.

11. The method of claim 9 wherein the exposed resin is cross-linked with the acid in a pre-defined imaged area.

12. The method of claim 9 wherein the resin has a melt viscosity below 5000 centistokes at 120° C.

13. The method of claim 9 further comprising mixing the resin and the photoacid generator at a temperature between 120° C. and 150° C. and filtering the mixture through a microfiber filter.

14. The method of claim 13, further comprising degassing the mixture.

15. The method of claim 9 wherein the photoacid generator comprises at least one of: 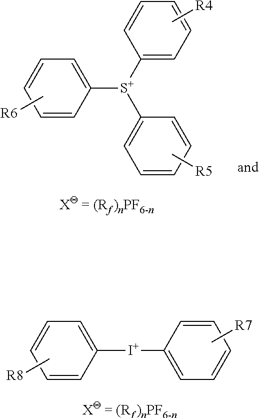
wherein:
R4, R5, R6, R7, and R8 are independently selected from H, alkyl, aryl, ester, amide, amine, nitrile, ether, and alcohol;
R_{f} is an alkyl fluoride;
X⁻ is a counterion; and
n is an integer from 0 to 5.

16. The method of claim 9, further comprising mixing the resin with a surface wetting agent.

17. The method of claim 9 wherein the resin comprises at least one of a SU-8 epoxy resin, a bisphenol-A epichlorohydrin epoxy resin, a glycidyloxypropyltrimethoxysilane silicone fluid, a dimethylsiloxane silicone fluid, and a resin modifier.

18. The method of claim 17, wherein the resin modifier has a viscosity between 1,000 and 10,000 cP at 25° C.

19. The method of claim 17, wherein the resin modifier has a hydroxyl number between 100 and 400.

20. The method of claim 9 wherein the dry film sheet is ultraviolet radiation sensitive and the photoacid generator is a triarylsulfonyl-fluoroalkyl polyfluorophosphate salt.
